(19) United States
(12) Patent Application Publication
(10) Pub. No.: US 2012/0276695 A1
(43) Pub. Date: Nov. 1, 2012

(54) Strained thin body CMOS with Si:C and SiGe stressor

(75) Inventors: Kangguo Cheng, Guilderland, NY (US); Bruce B. Doris, Slingerlands, NY (US); Ali Khakifirooz, Mountain View, CA (US); Pranita Kulkarni, Slingerlands, NY (US); Ghavam G. Shahidi, Pound Ridge, NY (US)

(73) Assignee: INTERNATIONAL BUSINESS MACHINES CORPORATION, Armonk, NY (US)

(21) Appl. No.: 13/098,352

(22) Filed: Apr. 29, 2011

(51) Int. Cl. H01L 21/8238

(52) U.S. Cl. 438/154; 257/E21.632

(57) ABSTRACT

A method is disclosed which is characterized as being process integration of raised source/drain and strained body for ultra thin planar and FinFET CMOS devices. NFET and PFET devices have their source/drain raised by selective epitaxy with in-situ p-type doped SiGe for the PFET device, and in-situ n-type doped Si:C for the NFET device. Such raised source/drains offer low parasitic resistance and they impart a strain onto the device bodies of the correct sign for respective carrier, electron or hole, mobility enhancement.

### BACKGROUND

The present invention relates to electronic devices of very large scale integration (VLSI) circuits. In particular, it relates to the fabrication of ultra thin body SOI FET devices.

### BRIEF SUMMARY

A method is disclosed which is characterized as being process integration of raised source/drain and strained body for ultra thin planar and FinFET CMOS devices. NFET and PFET devices have their source/drain raised by selective epitaxy with in-situ p-type doped SiGe for the PFET device, and in-situ n-type doped Si:C for the NFET device. Such raised source/drains offer low parasitic resistance and they impart a strain onto the device bodies of the correct sign for respective carrier, electron or hole, mobility enhancement.

### BRIEF DESCRIPTION OF THE SEVERAL VIEWS OF THE DRAWINGS

These and other features of the present invention will become apparent from the accompanying detailed description and drawings, wherein:

FIG. 1A through 1G schematically depict a sequence of processing steps for fabricating CMOS devices in a representative embodiment of the disclosure; and

FIG. 2A through 2E schematically depict a sequence of processing steps for fabricating CMOS devices in an alternate representative embodiment of the disclosure.

### DETAILED DESCRIPTION

It is understood that Field Effect Transistor-s (FET) arc well known in the electronic arts. Standard components of an FET are the source, the drain, the body in-between the source and the drain, and the gate, or gate-stack. The source and drain are commonly referred to a “source/drain”, especially in cases where there may be no need to distinguish between the two. In the instant disclosure the term “source/drain” will be used throughout. The gate is overlaying the body and is capable to induce a conducting channel in the body between the source and the drain. In advanced, deeply submicron, devices the source/drain are often augmented by extensions. The gate is typically separated from the body by the gate insulator. Depending whether the “on state” current is carried by electrons or holes, the FET comes as NFET or PFET. (In different nomenclature the NFET and PFET devices are often referred to as NMOS and PMOS devices.) It is also understood that frequently the NFET and PFET devices are used together in circuits. Such NFET PFET combination circuits may find applications in analogue circuits, or in digital circuits where they arc typically coupled into CMOS configurations. In circuit applications individual devices are usually separated from one another both physically and electrically by isolation. Such isolations are well known in the art, a typical one being, for instance, a shallow trench isolation (STI). Often the isolation is regarded as part of the FET device.

The most common material of microelectronics is silicon (Si), or more broadly, Si based materials. Si based materials are various alloys of Si in the same basic technological content as Si. Such Si based materials of significance for microelectronics are, for instance, the alloys of Si with other elements of the IV-th group of the periodic table, Group IV elements for brevity. Such alloys formed with Ge and C are silicon germanium (SiGe), and silicon carbon (Si:C). The devices in the embodiments of the present disclosure are typically of Si, and/or of Si alloyed with Ge or C. The semiconducting materials of the device bodies in representative embodiments of the invention are in a single-crystalline state.

FET devices that are characterized as being silicon-on-insulator (SOI) FETs arc known in the art. Such devices are formed in a layer of single crystal semiconductor material on top of an insulating layer. Typically the semiconductor material is a Si based single crystal material, often essentially pure Si. The insulating layer is typically a so called buried oxide (BOX) layer, which BOX layer, in turn, is over a silicon wafer piece. Generally in the art, the structure of the insulating layer and the Si wafer piece together is being referred to as the substrate.

SOI FETs have several versions. There are the planar kind, regularly referred to as just SOI FET, that are very much like the common FETs except for having an insulating substrate instead of the more common bulk semiconductor substrate. There are also SOI FinFET, or Tri-Gate devices. These are also FET devices but with a particular geometric configuration. These devices are non-planar, they are three dimensional structures hosted by a fin structure. In FinFETs, the body of the transistor is formed in a fin rising out of a planar background, typically having both vertical and horizontal surfaces. The gate of the FinFET may engage the top surface, as well as the vertically oriented body surfaces on both faces, or sidewalls, resulting in several planes being used for transistor body formation. Such FET devices, with fin-type bodies, have several advantages, as known in the art. The fin of the FinFET devices in embodiments of the instant application rises out of an insulating substrate, hence the SOI FinFET terminology.

In embodiments of the present invention the dimensions of fin structures that serve as fin-type device bodies may be of a height of about 5 nm to 50 nm, and of a width of between 3 nm to about 30 nm. The planar FETs in embodiments of the present invention, named ultra thin SOI (UTSOI) devices, may be fabricated in a Si layer over the insulating substrate, typically BOX, that may be less than 30 nm of thickness, typically in the 3 nm to 25 nm thickness range. The thickness of the UTSOI device body, as well as the source/drain thickness before being raised during fabrication, are essentially the same as the Si layer thickness on top of the BOX. The BOX thickness is in the range of 10 nm to 150 nm.

Microelectronics progress has been essentially synonymous with decreasing feature sizes. Decreased feature sizes allow for ever higher circuit counts, and increased circuit densities for integrated circuits (IC).

Along with advantages of miniaturization there are also problems arising due to smaller dimensions. For the soon to be realized 22 nm gate length technology, device choices having desirable properties are dwindling. Ultra thin body SOI FETs are one attractive choice for the 22 nm generation and beyond. Such device may be planar, UTSOI, or the FinFET kind.

A notable problem arising with ever smaller dimension devices, and in particular with, ultra thin body devices, is parasitic device resistance due to the source/drain. Part of the source/drain resistance is a contact resistance in the path of the current between metal wiring and the semiconductor source/drain. A mitigating procedure for reducing source/drain resistance is to raise, or thicken, the source/drain during device fabrication.

With decreasing dimensions there is also difficulty in maintaining performance improvements with each new device generation. One approach for improving performance is to increase carrier (electron and/or hole) mobilities. A promising avenue toward better carrier mobility is to apply tensile or compressive strain in the semiconductor body regions. Typically, it may be preferable to have the body of electron conduction type devices, such as NFET, in tensile stress, while to have the body of hole conduction type devices, such as PFET, in compressive stress.

Embodiments of the present invention teach process integration in ultra thin body FET fabrication, which process integration combines low resistance raised source/drain with strain in the device body. In embodiments of the present invention in-situ doped epitaxial deposition is used to raise the source/drain, achieving exceptionally low resistance, and at the same time, selecting a material for the epitaxial deposition to impart significant strain, of the right orientation, onto the device body. Such suitable materials may be SiGe and Si:C. In conventional processing, the raised source/drain (RSD) structure is made out of undoped semiconductor, usually undoped Si, and then implanted with n-type and p-type dopant species. An annealing step is needed to activate the dopants and remove the implant defects. In general, in advanced FET fabrication it is desirable to keep processing temperatures, and thermal budgets low, thus annealing steps should be minimized both in their numbers and their thermal budget. Furthermore, for ultra thin FinFET and UTSOI, the silicon layer maybe so thin that implantation may cause damage. Such damage may lead to poor quality epitaxy for source drains and high resistance. In addition, in the case of the FinFET, the RSD extensions should be uniform across the fin from top to bottom, which is particularly difficult to realize for tall tightly packed fins. The in-situ doped epi and out diffusion solves these problems. Hence in-situ doping for the RSD is advantageous in comparison to the separation of the growth and doping steps.

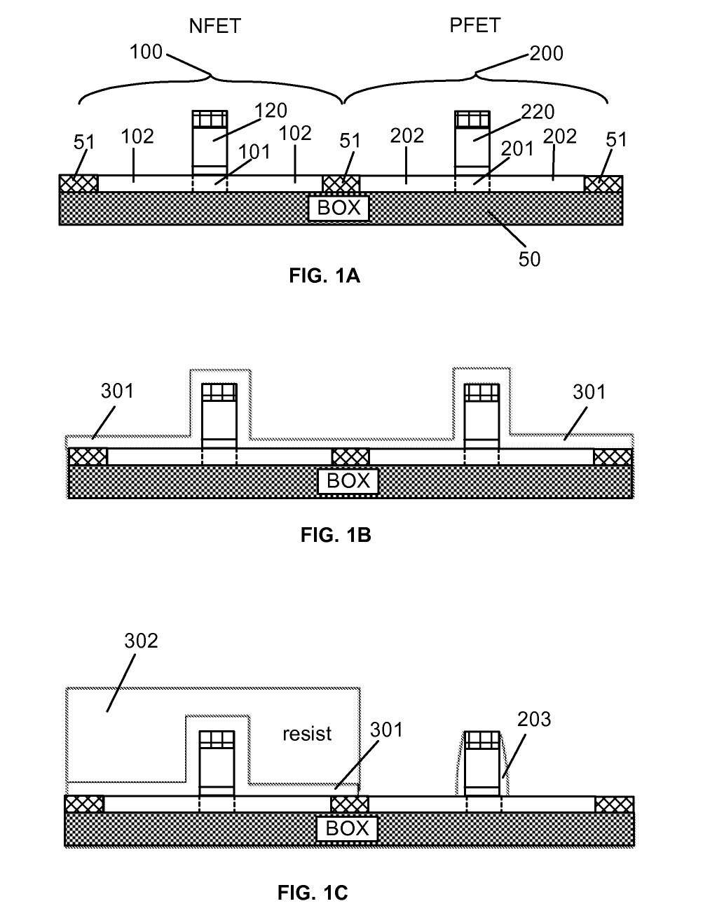

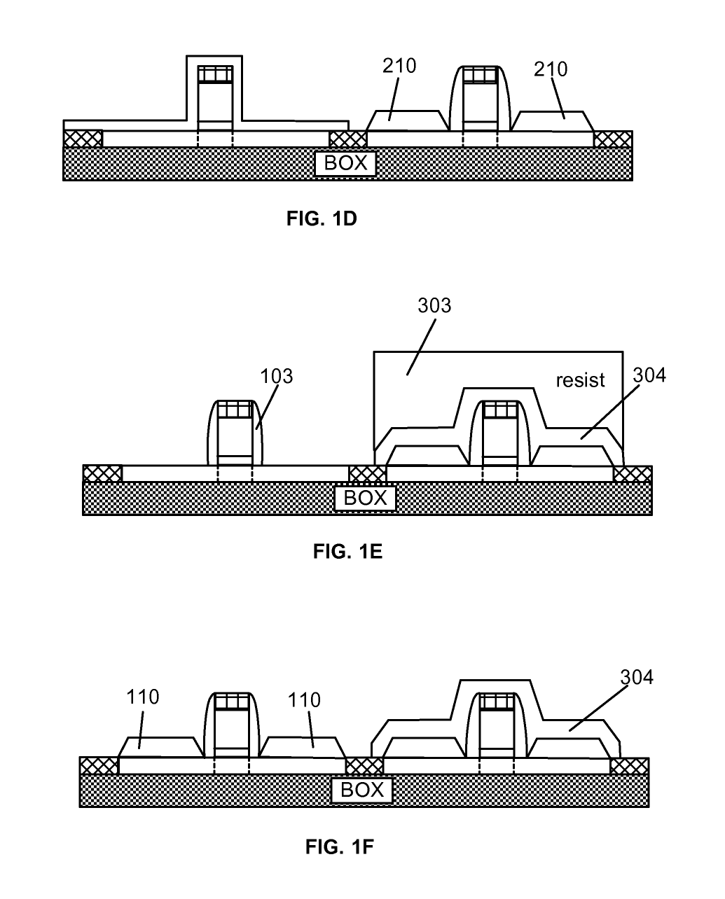

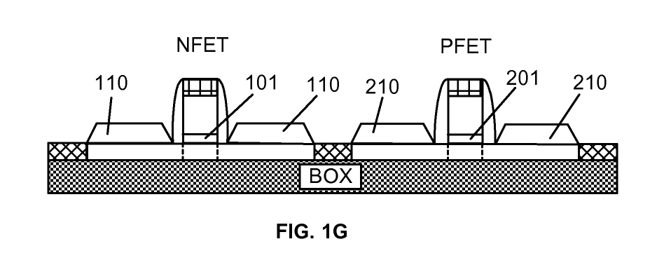

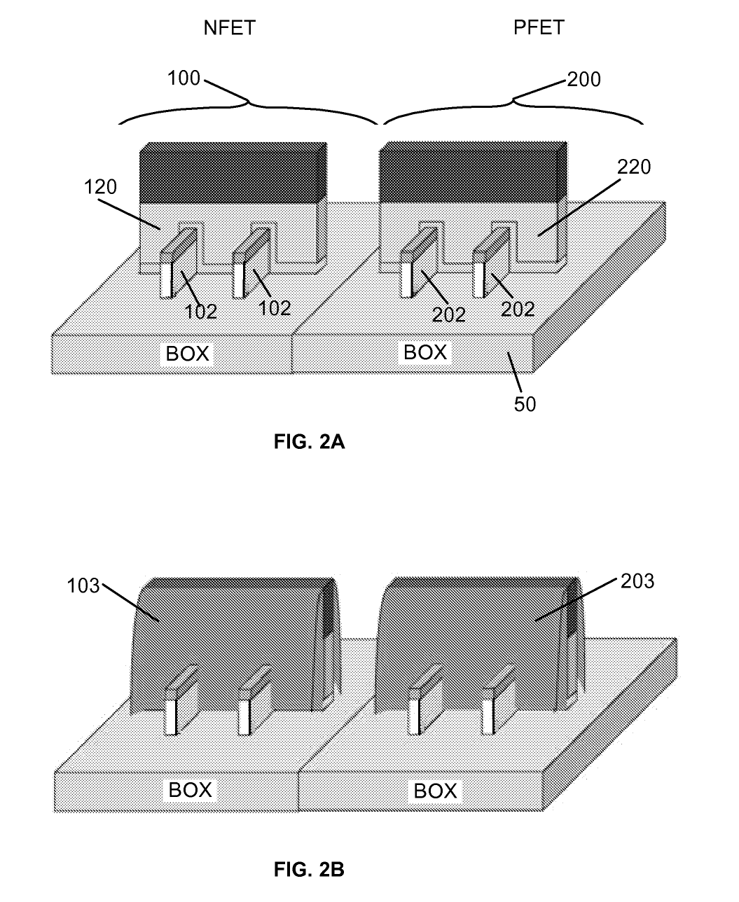

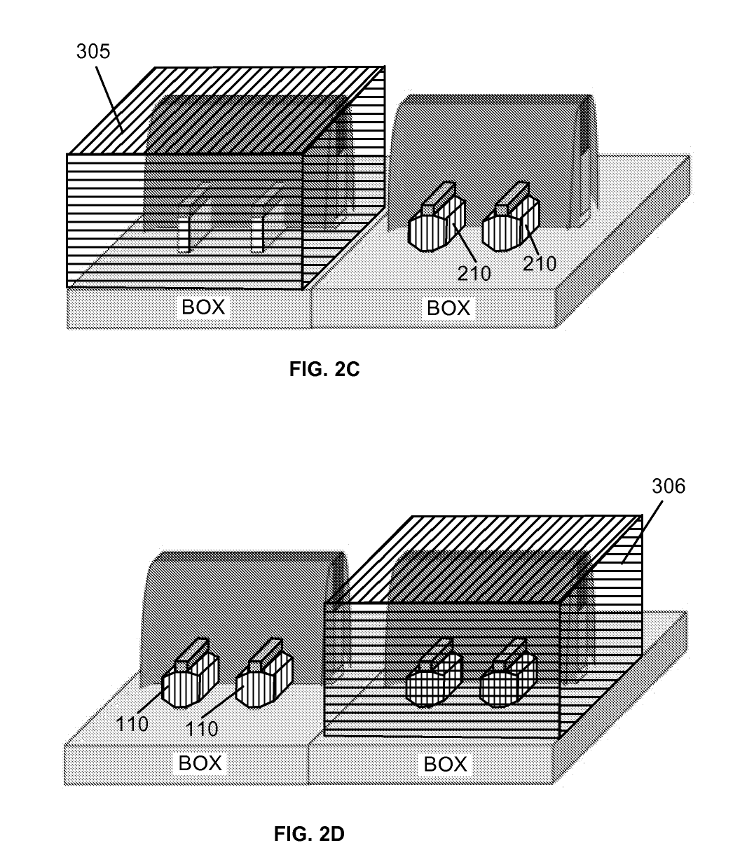

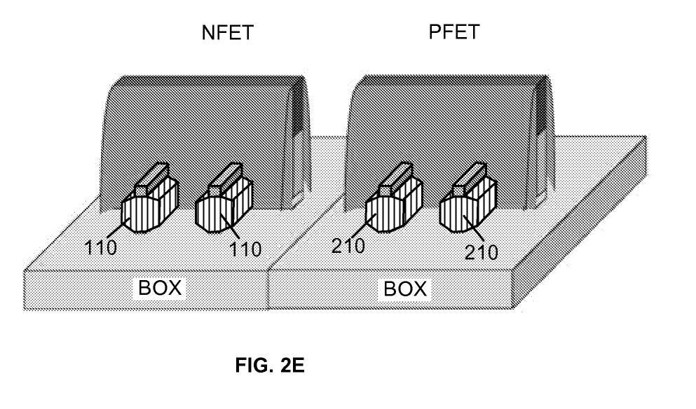

In presenting the processing integrations for low resistance source/drain and strained device body, two embodiments will be discussed in more detail. FIGS. 1A to 1G present one representative embodiment, and FIGS. 2A to 2E present an alternate representative embodiment. Each of the embodiments may be applied with either the planar UTSOI, or with the FinFET devices. For illustration purposes only, without intent of limitation, in the figures and in the discussion one of the embodiments will be presented using UTSOI devices as example, and an alternate embodiment will be presented using FinFET devices as example.

FIGS. 1A through 1G schematically depict a sequence of processing steps for fabricating CMOS devices in a representative embodiment of the disclosure. These figures show UTSOI devices, but as just discussed above, the sequence of processing steps are just as applicable for FinFET devices.

Manufacturing of CMOS structures is established in the art. It is understood that there are large number of steps involved in such processing, and each step may have practically endless variations known to those skilled in the art. For embodiments of this disclosure it is understood that the whole range of known processing techniques are available for fabricating the devices, and only those process steps will be detailed that arc related to the embodiments of the present invention.

FIG. 1A shows a stage in the fabrication processing flow of NFET and PFET devices that may serve as starting point for the steps of the embodiments of the present disclosure. The NFET and PFET devices are accepted at the stage shown in FIG. 1A for further processing. The term of accepting is intended to be inclusive of any possible manner by which one may arrive at this initial stage of the structure. Typically the processing may have just reached this stage of fabrication, or samples may have been supplied in some other manner. The NFET gate 120 and the PFET gate 220 have been already formed and patterned. The NFET and PFET devices have respective NFET and PFET sections 100, 200. They have respective device bodies, 101, 201, and have respective source/drain regions 102, 202. The bodies and the source/drain regions arc fabricated in the ultra thin semiconductor, typically Si, layer on top of the BOX 50 insulating layer. In circuit applications individual devices are usually separated from one another both physically and electrically by isolation. Such isolations arc well known in the art, a typical one being, for instance, a shallow trench isolation (STI) 51.

The sequence of figures from FIG. 1A to FIG. 1G show the evolution of the same structure through a series of processing steps. In order to avoid crowding the Figures, elements once identified with indicator numbers generally will not be such identified in later stages of the processing, with the understanding that the same indicator number would identify the same element again at this later stage. In this manner the elements that are changed, or added, in a particular step may be more clearly identified.

FIG. 1B shows the fabrication flow after the step of blanket depositing an insulating material layer 301. Such a layer may be of SIN or SiO₂, and it serves as a sidewall spacer material.

FIG. 1C shows as a first photoresist 302 is used to cover the NFET region 100, and shows that the spacer material 301 has been directionally etched over the surfaces not covered by the photoresist 302. Such etching is usually done as a reactive ion etching (RIE) step, which, when completed, results in the spacer 203 formation for the PFET device.

FIG. 1D shows the state of the process flow after the first photoresist has been stripped. Next, the structures typically arc cleaned. Lastly, an in-situ p-doped, selective, epitaxial growth of SiGe has been performed, resulting in a raised source/drain (RSD) 210 for the PFET device.

Epitaxial growth is a known technique of the VLSI fabrication art. In describing a structure, the adjective “epitaxial” is typically used to indicate that a particular material has been epitaxially grown. The structural consequence of epitaxial deposition is that the deposited material and the host material, at their common interface, have the same symmetry and crystalline orientation. Further terms that may be used, such as “epitaxial relation”, “epitaxially”, “epitaxy”, “epi”, “epitaxial growth” etc. carry their customary usage, namely crystalline continuity across the interface. Typical techniques used in epitaxy may include molecular beam epitaxy (MBE), chemical vapor deposition (CVD), ultra high vacuum CVD (UHCVD), rapid thermal CVD (RTCVD), or further known methods.

Selective epitaxial growth means that the epi deposition only takes place on exposed surfaces that have proper crystalline qualities for accepting the growth material. In-situ doping with p-type dopants may he achieved by adding a carrier gas, for instance diborane, during the epi growth process. The p-type dopant in respective embodiments of the invention may be B. With in-situ doping, B concentrations as high as 8×10²⁰/cm³, may he reached, while processing temperature would stay below about 750° C. The high carrier concentration in the raised source/drain 210 assures low contact resistance, and sufficient amount of material for forming a contact, typically with a silicide.

The epitaxially deposited material for the PFET device may be selected as SiGe. Adding Ge to the Si further lowers the external resistance for PFET, and by having a larger lattice constant than Si, Ge causes strain in the PFET source/drain 202. The strain in the source/drain, in turn imparts a compressive strain into the PFET device body 201. As discussed earlier, for PFET devices a compressive strain in the device body increases carrier mobility, hence enhances device performance. The concentration of Ge in the raised source/drain 210 of the PFET device may be selected to be between 25% and 45%. Following the epitaxial deposition an annealing step, such as a 1000-1010° C. spike anneal step, may be used to drive the p-dopants into the p-body 201, to form a source/drain extension for the PFET.

FIG. 1E shows the state of fabrication after a few more steps. A hardmask 304, that can be either SiN or SiO₂, and a second photoresist layer 303 is blanket deposited. Next, the second photoresist layer 303 is removed form the NFET region, exposing the hardmask 304 over the NFET region. This hardmask 304 is next removed from the NFET region using a dry plasma etch as it is known in the art. These steps leave the PFET region covered with the hardmask 304 and photoresist 303, while the NFET region is exposed. After this, a directional RIE step is carried out, resulting in the sidewall spacers 103 for the NFET device. It is this stage that is displayed in FIG. 1E.

Next, the second photoresist layer 303 is removed, and the structure optionally cleaned. This is followed by an in-situ n-doped, selective, epitaxial growth of Si:C, resulting in a raised source/drain, RSD, 110 for the NFET device. In-situ doping with n-type dopants may be achieved by adding a carrier gas, for instance phosphine, during the cpi growth process. The n-type dopant in respective embodiments of the invention may be P. With in-situ doping, P concentrations as high as 7×10²⁰/cm³, may be reached, while processing temperature would stay below about 750° C. The high carrier concentration in the raised source/drain 110 assures low contact resistance, and sufficient amount of material for forming a contact, typically with a silicide.

The epitaxially deposited material for the NFET device may be selected as Si:C. Adding C to Si, which has a smaller lattice constant than Si, causes strain in the NFET source/drain 102. The strain in the source/drain, in turn, imparts a tensile strain into the NFET device body 101. As discussed earlier, for NFET devices a tensile strain in the device body increases carrier mobility, hence enhances device performance. The concentration of C in the RSD 110 of the NFET device may be selected to he between 0.5% and 2%. Following the epitaxial deposition an optional annealing step, such as a 1000-1010° C. spike anneal step, may be used to drive the n-dopants into the NFET device body 101, to form a source/drain extension for the NFET.

FIG. 1G exhibits the state of the processing flow when steps associated with embodiments of the instant invention arc completed. Both the NFET and PFET devices have highly conductive RSDs 110, 210. The RSD for each device imparts a strain onto the device bodies of the correct sign for respective carrier, electron and hole, mobility enhancement. Numerical simulations show that the compressive strain in the PFET body 101 under the influence of the SiGe RSD can reach 800 MPa, while the tensile strain in the NFET body 201 under the influence of the Si:C RSD can reach 400 MPa.

In the discussion presented with reference to FIGS. 1A to 1G, the RSD for the PFET device 210 was deposited before the one for the NFET device 110. Of course it is understood, that one could equally have the order reversed, with RSD processing for the NFET done before the one for the PFET.

FIG. 2A through 2E schematically depict a sequence of processing steps for fabricating CMOS devices in an alternate representative embodiment of the disclosure. These figures show FinFET devices, but as discussed earlier, the sequence of processing steps are just as applicable for planar UTSOI devices.

The indicator numbers in FIG. 2A through 2E that are the same as those in FIGS. 1A to 1G, refer to the same elements. For instance in FIG. 2A, the NFET and PFET regions arc again 100 and 200, the source/drains 102 and 202, and so on.

FIG. 2A shows a stage in the fabrication processing flow of NFET and PFET devices that may serve as starting point for embodiments of the present disclosure. The NFET and PFET devices arc accepted at the stage shown in FIG. 2A for further processing. The NFET gate 120 and the PFET gate 220 have been already formed and patterned. The NFET and PFET devices have respective NFET and PFET sections 100, 200. The bodies and the source/drain regions 102, 202 are fabricated in thin fins, typically of Si.

FIG. 2B shows the state of the process flow after several steps. An insulating material layer is blanket deposited. Such a layer may be of SiN or SiO₂, and it serves as sidewall spacer material. Next, the spacer material layer is directionally etched, and spacer sidewalls 103, 203 are formed for both the NFET device and the PFET device.

Ensuing, the NFET is blocked, 305 FIG. 2C, for instance with a hardmask, and an in-situ p-doped, selective, epitaxial growth of SiGe, is performed, resulting in a RSD 210 for the PFET device. The p-type dopant in respective embodiments of the invention may be B.

In FIGS. 2D and 2C the blocking of the NFET device the PFET device is shown only in a symbolic manner to allow for viewing the underlying device structure.

Having grown the SiGe RSD for the PFET device, the PFET device is blocked, 306 FIG. 2D, and an in-situ n-doped, selective, epitaxial growth of Si:C, is performed, resulting in a RSD 110 for the NFET device. The n-type dopant in respective embodiments of the invention may be P.

FIG. 2E exhibits the state of the processing now when steps associated with embodiments of the instant invention are completed. Both the NFET and PFET devices have highly conductive RSDs 110, 210. The RSD for each device imparts a strain onto the device bodies of the correct sign for respective carrier, electron and hole, mobility enhancement.

Auxiliary and/or optional steps, such as for instance, cleaning and annealing, not mentioned in reference to FIGS. 2A to 2E but discussed in reference to FIGS. 1A to 1G, are understood that may just as well have been performed in the alternate embodiments, as well. Numerical values, for instance doping concentrations, given earlier again carry over to the embodiments that reference FIGS. 2A to 2E. Similarly, while in the discussion presented with reference to FIGS. 2A to 2E, the RSD for the PFET device 210 was deposited before the one for the NFET device 110, it is understood that one could equally have the order reversed, with RSD processing for the NFET done before the one for the PFET.

Having completed the steps associated with embodiments of the instant disclosure, the process flow continues till the NFET and PFET devices, typically configured into CMOS structures, are fully completed.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures arc to be regarded in an illustrative rather than a restrictive sense, and all such modifications are intended to be included within the scope of present invention.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as “under,” “upper”, “side,” “over”, “underneath” etc., as used herein refer to relative location and orientation of various portions of the structures with respect to one another, and are not intended to suggest that any particular absolute orientation with respect to external objects is necessary or required.

The foregoing specification also describes processing steps. it is understood that the sequence of such steps may vary in different embodiments from the order that they were detailed in the foregoing specification. Consequently, the ordering of processing steps in the claims, unless specifically stated, for instance, by such adjectives as “before”, “ensuing”, “after”, etc., does not imply or necessitate a fixed order of step sequence.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art. The scope of the invention is defined by the appended claims.

1. A method, comprising:
accepting NFET and PFET devices fabricated to the point of completion of gate patterning, wherein said NFET and PFET devices have respective NFET and PFET sections, have respective device bodies, and have respective source/drain regions;
blanket depositing an insulating material layer;
covering said NFET section with a first photoresist layer and directionally etching said insulating material layer, wherein forming a sidewall spacer for said PFET device;
removing said first photoresist layer, and by selective epitaxy depositing in-situ p-type doped SiGe over said PFET device source/drain region, wherein said PFET device source/drain region is being raised, and a compressive strain is being imparted into said PFET device body;
blanket depositing a hard mask layer, and covering said PFET section with a second photoresist layer;
in said NFET section, etching away said hard mask layer, and directionally etching said insulating material layer, wherein forming a sidewall spacer for said NFET device;
removing said second photoresist layer, and by selective epitaxy depositing in-situ n-type doped Si:C over said NFET device source/drain region, wherein said NFET device source/drain region is being raised, and a tensile strain is being imparted into said NFET device body; and
wherein said method is characterized as being process integration of raised source/drain and strained body, for ultra thin SOI CMOS.

2. The method of claim 1, wherein said NFET and PFET devices are planar devices.

3. The method of claim 1, wherein said NFET and PFET devices are FinFET devices.

4. The method of claim 1, wherein said in-situ p-type doped SiGe is B doped.

5. The method of claim 1, wherein said in-situ p-type doped SiGe has between 15% and 45% of Ge concentration.

6. The method of claim 1, wherein said in-situ n-type doped Si:C is P doped.

7. The method of claim 1, wherein said in-situ p-type doped Si:C has between 0.5% and 2% of C concentration.

8. A method, comprising:
accepting NFET and PFET devices fabricated to the point of completion of gate patterning, wherein said NFET and PFET devices have respective NFET and PFET sections, have respective device bodies, and have respective source/drain regions;
blanket depositing an insulating material layer;
directionally etching said insulating material layer, wherein forming a sidewall spacer for both said NFET device and said PFET device;
blocking said NFET section, and by selective epitaxy depositing in-situ p-type doped SiGe over said PFET device source/drain region, wherein said PFET device source/drain region is being raised, and a compressive strain is being imparted into said PFET device body;
blocking said PFET section, and by selective epitaxy depositing in-situ n-type doped Si:C over said NFET device source/drain region, wherein said NFET device source/drain region is being raised, and a tensile strain is being imparted into said NFET device body; and
wherein said method is characterized as being process integration of raised source/drain and strained body, for ultra thin SOI CMOS.

9. The method of claim 8, wherein said NFET and PFET devices are planar devices.

10. The method of claim 8, wherein said NFET and PFET devices are FinFET devices.

11. The method of claim 8, wherein said in-situ p-type doped SiGe is B doped.

12. The method of claim 8, wherein said in-situ p-type doped SiGe has between 25% and 45% of Ge concentration.

13. The method of claim 8, wherein said in-situ n-type doped Si:C is P doped.

14. The method of claim 8, wherein said in-situ p-type doped Si:C has between 0.5% and 2% of C concentration.

15. A method, comprising:
accepting NFET and PFET devices fabricated to the point of completion of gate patterning, wherein said NFET and PFET devices have respective NFET and PFET sections, have respective device bodies, and have respective source/drain regions;
blanket depositing an insulating material layer;
covering said PFET section with a first photoresist layer and directionally etching said insulating material layer, wherein forming a sidewall spacer for said NFET device;
removing said first photoresist layer, and by selective epitaxy depositing in-situ n-type doped Si:C over said NFET device source/drain region, wherein said NFET device source/drain region is being raised, and a tensile strain is being imparted into said NFET device body;
blanket depositing a hard mask layer, and covering said NFET section with a second photoresist layer;
in said PFET section, etching away said hard mask layer, and directionally etching said insulating material layer, wherein forming a sidewall spacer for said PFET device;
removing said second photoresist layer, and by selective epitaxy depositing in-situ p-type doped SiGe over said PFET device source/drain region, wherein said PFET device source/drain region is being raised, and a compressive strain is being imparted into said PFET device body; and
wherein said method is characterized as being process integration of raised source/drain and strained body, for ultra thin SOI CMOS.

16. The method of claim 15, wherein said NFET and PFET devices are planar devices.

17. The method of claim 15, wherein said NFET and PFET devices are FinFET devices.

18. The method of claim 15, wherein said in-situ p-type doped SiGe is B doped.

19. The method of claim 15, wherein said in-situ n-type doped Si:C is P doped.
